(19) United States
(12) Patent Application Publication
(10) Pub. No.: US 2026/0223685 A1
(43) Pub. Date: Jul. 30, 2026

(54) PACKAGE COMPRISING AN INTEGRATED DEVICE, AN ENCAPSULATION LAYER AND METALLIZATION PORTIONS

(71) Applicant: QUALCOMM Incorporated, San Diego, CA (US)

(72) Inventors: Akshay BILAGI, San Diego, CA (US); Sun Woong YUN, San Diego, CA (US)

(21) Appl. No.: 19/040,603

(22) Filed: Jan. 29, 2025

(51) Int. Cl. H01L 23/00; H01L 23/31; H01L 23/498; H01L 23/552

(52) U.S. Cl. CPC H10W 42/20; H10W 90/401; H10W 72/072; H10W 72/07236; H10W 72/227; H10W 72/241; H10W 74/141; H10W 90/724

(57) ABSTRACT

A package comprising an integrated device; a plurality of post interconnects coupled to the integrated device; a first metallization portion coupled to the integrated device through a first plurality of solder interconnects; a second metallization portion coupled to the integrated device through a second plurality of solder interconnects; an encapsulation layer at least partially encapsulating the integrated device, the first metallization portion, the second metallization portion, the plurality of post interconnects, the first plurality of solder interconnects and the second plurality of solder interconnects; and a plurality of pillar interconnects coupled to the first metallization portion, the second metallization portion and the plurality of post interconnects.

### FIELD

Various features relate to packages with integrated devices.

### BACKGROUND

A package may include a substrate and integrated devices. These components are coupled together to provide a package that may perform various electrical functions. There is an ongoing need to provide better performing packages, including packages with better electrical performances. Moreover, there is also an ongoing need to reduce and/or minimize the overall size of the packages.

### SUMMARY

Various features relate to packages with integrated devices.

One example provides a package comprising an integrated device; a plurality of post interconnects coupled to the integrated device; a first metallization portion coupled to the integrated device through a first plurality of solder interconnects; a second metallization portion coupled to the integrated device through a second plurality of solder interconnects; an encapsulation layer at least partially encapsulating the integrated device, the first metallization portion, the second metallization portion, the plurality of post interconnects, the first plurality of solder interconnects and the second plurality of solder interconnects; and a plurality of pillar interconnects coupled to the first metallization portion, the second metallization portion and the plurality of post interconnects.

Another example provides a method for fabricating a package. The method provides an integrated device, wherein a plurality of post interconnects are coupled to the integrated device. The method couples a first metallization portion to the integrated device through a first plurality of solder interconnects. The method couples a second metallization portion to the integrated device through a second plurality of solder interconnects. The method forms an encapsulation layer that at least partially encapsulates the integrated device, the first metallization portion, the second metallization portion, the plurality of post interconnects, the first plurality of solder interconnects and the second plurality of solder interconnects. The method forms a plurality of pillar interconnects that are coupled to the first metallization portion, the second metallization portion and the plurality of post interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes integrated devices, an encapsulation layer and metallization portions.

FIG. 2 illustrates an exemplary cross sectional plan view of a package that includes integrated devices, an encapsulation layer and metallization portions.

FIG. 3 illustrates an exemplary cross sectional profile view of a package that includes integrated devices, an encapsulation layer and metallization portions.

FIGS. 4A-4C illustrate an exemplary sequence for fabricating metallization portions.

FIG. 5 illustrates an exemplary flow chart of a method for fabricating metallization portions

FIGS. 6A-6D illustrate an exemplary sequence for fabricating a package that includes integrated devices, an encapsulation layer and metallization portions.

FIG. 7 illustrates an exemplary flow chart of a method for fabricating a package that includes integrated devices, an encapsulation layer and metallization portions.

FIGS. 8A-8C illustrate an exemplary sequence for fabricating a substrate.

FIG. 9 illustrates an exemplary flow chart of a method for fabricating a substrate.

FIGS. 10A-10B illustrate an exemplary sequence for fabricating a metallization portion.

FIG. 11 illustrates an exemplary flow chart of a method for fabricating a metallization portion.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device; a plurality of post interconnects coupled to the integrated device; a first metallization portion coupled to the integrated device through a first plurality of solder interconnects; a second metallization portion coupled to the integrated device through a second plurality of solder interconnects; an encapsulation layer at least partially encapsulating the integrated device, the first metallization portion, the second metallization portion, the plurality of post interconnects, the first plurality of solder interconnects and the second plurality of solder interconnects; and a plurality of pillar interconnects coupled to the first metallization portion, the second metallization portion and the plurality of post interconnects. The package may provide high density interconnects in a compact form factor.

### Exemplary Package Comprising an Integrated Device and Metallization Portions

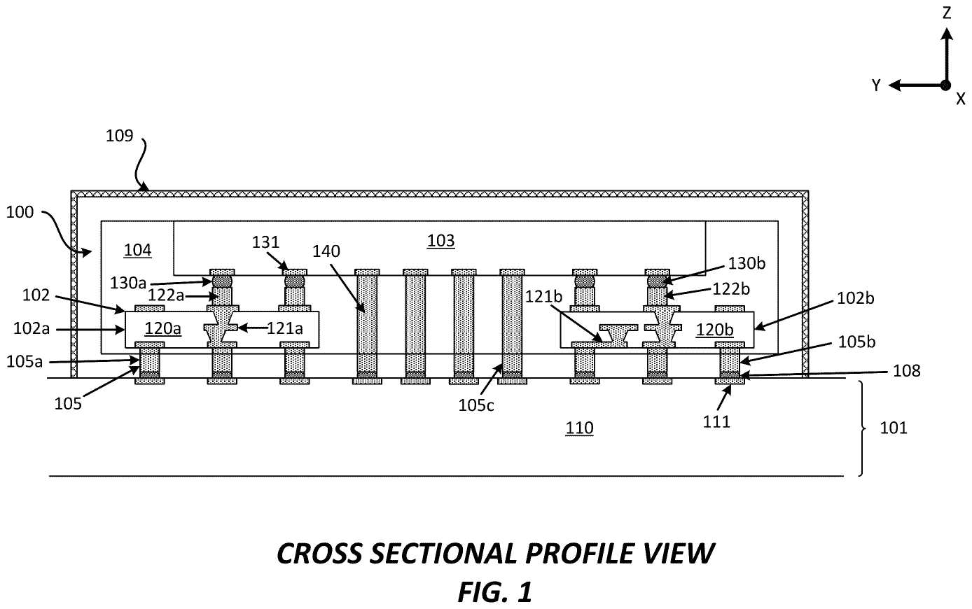

FIG. 1 illustrates a cross sectional profile view of a package 100 that includes integrated devices and metallization portions. The package 100 is coupled to a board 101 through a plurality of solder interconnects 108. The board 101 includes at least one board dielectric layer 110 and a plurality of board interconnects 111. The board 101 may include a printed circuit board (PCB). In some implementations, the package 100 may be coupled to a substrate (e.g., organic substrate, laminate substrate) instead of the board 101.

The package 100 includes an integrated device 103, a plurality of metallization portions 102, a plurality of post interconnects 140, an encapsulation layer 104 and a plurality of pillar interconnects 105. The integrated device 103 includes a plurality of pad interconnects 131. The plurality of post interconnects 140 are coupled to the integrated device 103. The plurality of post interconnects 140 may be coupled to and touching the plurality of pad interconnects 131 of the integrated device 103.

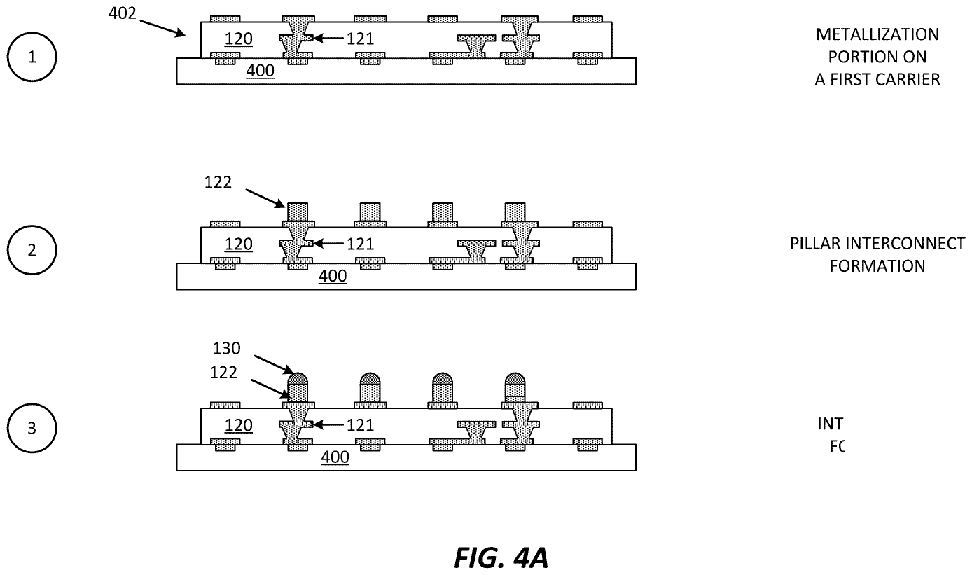

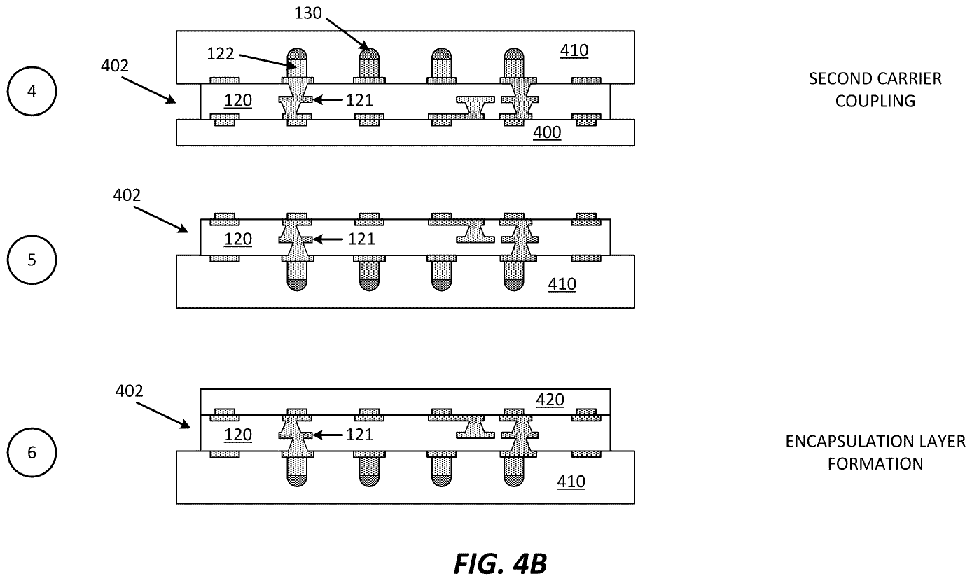

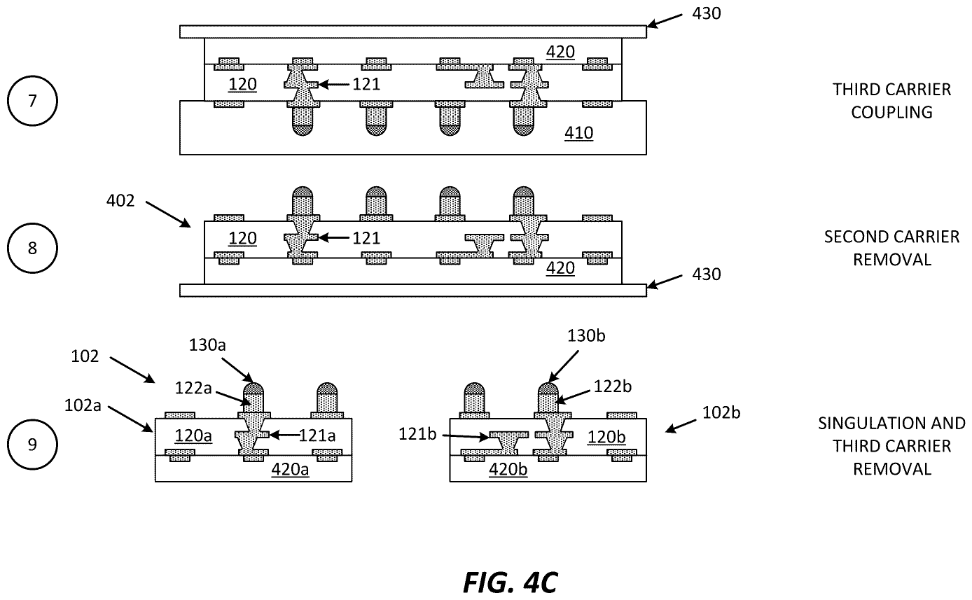

The plurality of metallization portions 102 include a metallization portion 102a and a metallization portion 102b. The plurality of metallization portions 102 may be a plurality of redistribution portions. The metallization portion 102a includes at least one dielectric layer 120a and a plurality of metallization interconnects 121a. A plurality of post interconnects 122a may be coupled to the plurality of metallization interconnects 121a. In some implementations, the plurality of post interconnects 122a may be considered part of the metallization portion 102a. The metallization portion 102b includes at least one dielectric layer 120b and a plurality of metallization interconnects 121b. A plurality of post interconnects 122b may be coupled to the plurality of metallization interconnects 121b. In some implementations, the plurality of post interconnects 122b may be considered part of the metallization portion 102b. FIGS. 4A-4C illustrate an example of fabricating a metallization portion.

The metallization portion 102a is coupled to the integrated device 103 through a plurality of solder interconnects 130a. The plurality of solder interconnects 130a may be coupled to the plurality of post interconnects 122a and the plurality of pad interconnects 131 of the integrated device 103.

The metallization portion 102b is coupled to the integrated device 103 through a plurality of solder interconnects 130b. The plurality of solder interconnects 130b may be coupled to the plurality of post interconnects 122b and the plurality of pad interconnects 131 of the integrated device 103.

The encapsulation layer 104 at least partially encapsulates the integrated device 103, the plurality of post interconnects 140, the metallization portion 102a and the metallization portion 102b. The encapsulation layer 104 may include a mold, a resin, an epoxy and/or a filler. The plurality of post interconnects 140 may be considered as a plurality of through encapsulation layer via interconnects. The encapsulation layer 104 may at least partially encapsulate the plurality of solder interconnects 130a, the plurality of solder interconnects 130b, the plurality of post interconnects 122a and/or the plurality of post interconnects 122b.

The plurality of post interconnects 140 may be located laterally between the metallization portion 102a and the metallization portion 102b. The metallization portion 102a partially overlaps vertically with the integrated device 103. The metallization portion 102b partially overlaps vertically with the integrated device 103.

The plurality of pillar interconnects 105 are coupled to the metallization portion 102a, the plurality of post interconnects 140 and the metallization portion 102b. The plurality of pillar interconnects 105 comprise a plurality of pillar interconnects 105a, a plurality of pillar interconnects 105b and a plurality of pillar interconnects 105c. The plurality of pillar interconnects 105a are coupled to the plurality of metallization interconnects 121a of the metallization portion 102a. The plurality of pillar interconnects 105b are coupled to the plurality of metallization interconnects 121b of the metallization portion 102b. The plurality of pillar interconnects 105c are coupled to the plurality of post interconnects 140. In some implementations, the combination of the plurality of pillar interconnects 105c and the plurality of post interconnects 140 may be considered as a plurality of pillar interconnects or as a plurality of post interconnects.

The package 100 is coupled to the board 101 through a plurality of solder interconnects 108. The plurality of solder interconnects 108 are coupled to the plurality of pillar interconnects 105 and the plurality of board interconnects 111. The package 100 provide a compact form factor with high density interconnects. The metallization portion 102a and/or the metallization portion 102b help provide high density interconnects in the package 100. This helps provide a compact package (e.g., package with compact form factor) with high density interconnects.

A shield 109 may be coupled to the board 101. The shield 109 may at least partially surround the package 100. The shield 109 may laterally surround the package 100. The shield 109 may be an electromagnetic interference (EMI) shield. The shield 109 may include a metal material. The shield 109 may cover and/or surround the upper portion of the package 100. The shield 109 may be coupled to the board 101 through an adhesive and/or a mechanical coupling. A stamping process may be used to form the shield 109. The shield 109 may include one or more openings. Different implementations may use a shield with different shapes and/or sizes.

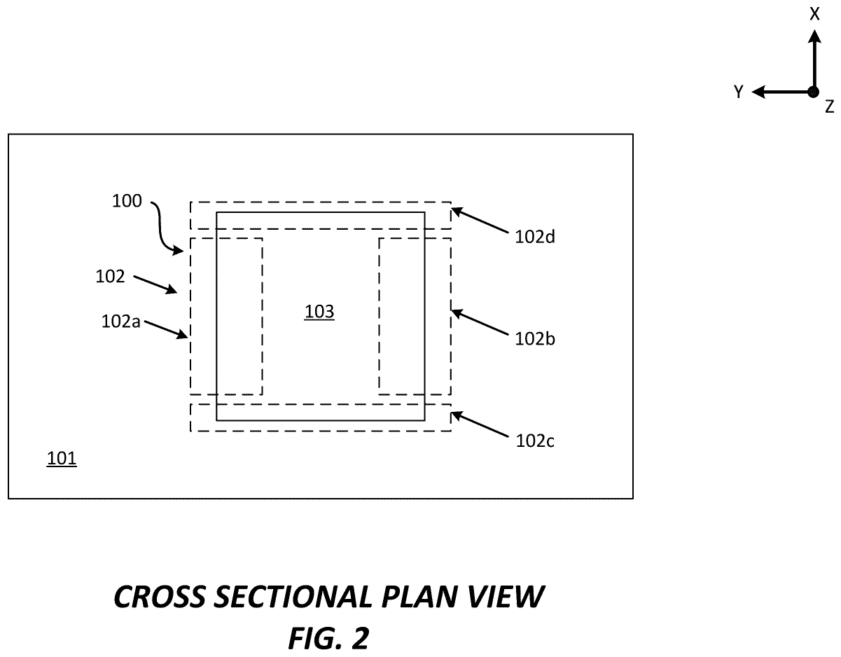

FIG. 2 illustrates an exemplary cross sectional plan view of the package 100. The package 100 includes the integrated device 103 and a plurality of metallization portions 102. The package 100 is coupled to the board 101. The plurality of metallization portions 102 include a metallization portion 102a, a metallization portion 102b, a metallization portion 102c and the metallization portion 102d. The metallization portion 102a vertically overlaps with a first edge of the integrated device 103. The metallization portion 102b vertically overlaps with a second edge of the integrated device 103. The metallization portion 102c vertically overlaps with a third edge of the integrated device 103. The metallization portion 102d vertically overlaps with a fourth edge of the integrated device 103. It is noted that the different metallization portions may vertically overlap (e.g., partial vertical overlap, complete vertical overlap) with the integrated device 103 differently. Moreover, different implementations may have different number of metallization portions. Different implementations may have metallization portions with different lateral sizes and/or lateral shapes.

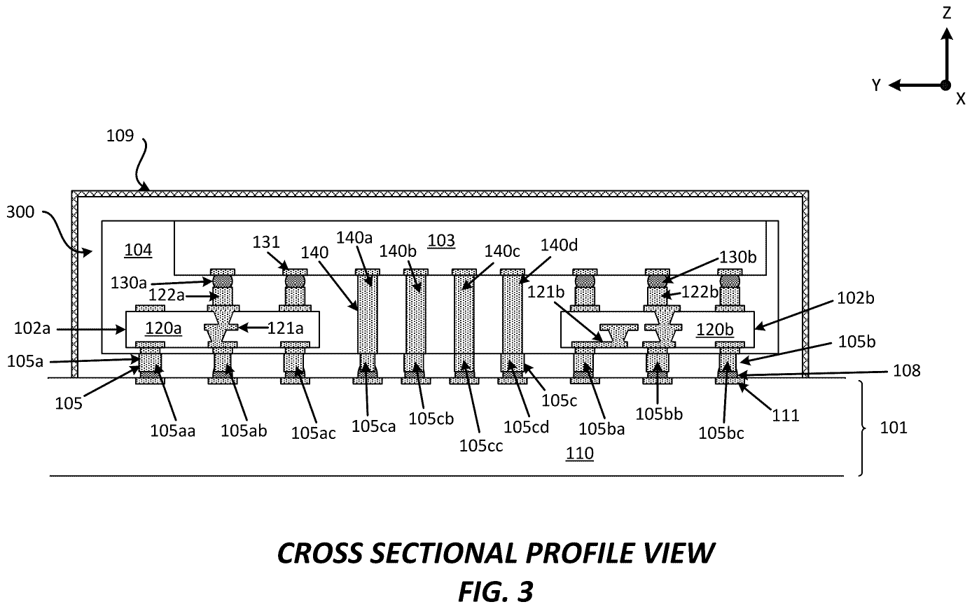

FIG. 3 illustrates a cross sectional profile view of a package 300 that includes integrated devices and metallization portions. The package 300 is coupled to a board 101 through a plurality of solder interconnects 108. The board 101 includes at least one board dielectric layer 110 and a plurality of board interconnects 111. The board 101 may include a printed circuit board (PCB). In some implementations, the package 300 may be coupled to a substrate (e.g., organic substrate, laminate substrate) instead of the board 101. The package 300 is similar to the package 100 of FIG. 1. The package 300 illustrates how different interconnects may be differently aligned with other interconnects.

The package 300 includes an integrated device 103, a plurality of metallization portions 102, a plurality of post interconnects 140, an encapsulation layer 104 and a plurality of pillar interconnects 105. The integrated device 103 includes a plurality of pad interconnects 131. The plurality of post interconnects 140 are coupled to the integrated device 103. The plurality of post interconnects 140 may be coupled to and touching the plurality of pad interconnects 131 of the integrated device 103. The plurality of post interconnects 140 include a post interconnect 140a, a post interconnect 140b, a post interconnect 140c and a post interconnects 140d.

The plurality of metallization portions 102 include a metallization portion 102a and a metallization portion 102b. The plurality of metallization portions 102 may be a plurality of redistribution portions. The metallization portion 102a includes at least one dielectric layer 120a and a plurality of metallization interconnects 121a. The plurality of metallization interconnects 121a may include a plurality of redistribution interconnects. A plurality of post interconnects 122a may be coupled to the plurality of metallization interconnects 121a. In some implementations, the plurality of post interconnects 122a may be considered part of the metallization portion 102a. The metallization portion 102b includes at least one dielectric layer 120b and a plurality of metallization interconnects 121b. The plurality of metallization interconnects 121b may include a plurality of redistribution interconnects. A plurality of post interconnects 122b may be coupled to the plurality of metallization interconnects 121b. In some implementations, the plurality of post interconnects 122b may be considered part of the metallization portion 102b. FIGS. 4A-4C illustrate an example of fabricating a metallization portion.

The metallization portion 102a is coupled to the integrated device 103 through a plurality of solder interconnects 130a. The plurality of solder interconnects 130a may be coupled to the plurality of post interconnects 122a and the plurality of pad interconnects 131 of the integrated device 103.

The metallization portion 102b is coupled to the integrated device 103 through a plurality of solder interconnects 130b. The plurality of solder interconnects 130b may be coupled to the plurality of post interconnects 122b and the plurality of pad interconnects 131 of the integrated device 103.

The encapsulation layer 104 at least partially encapsulates the integrated device 103, the plurality of post interconnects 140, the metallization portion 102a and the metallization portion 102b. The encapsulation layer 104 may include a mold, a resin, an epoxy and/or a filler. The plurality of post interconnects 140 may be considered as a plurality of through encapsulation layer via interconnects. The encapsulation layer 104 may at least partially encapsulate the plurality of solder interconnects 130a, the plurality of solder interconnects 130b, the plurality of post interconnects 122a and/or the plurality of post interconnects 122b.

The plurality of post interconnects 140 may be located laterally between the metallization portion 102a and the metallization portion 102b. The metallization portion 102a partially overlaps vertically with the integrated device 103. The metallization portion 102b partially overlaps vertically with the integrated device 103.

The plurality of pillar interconnects 105 are coupled to the metallization portion 102a, the plurality of post interconnects 140 and the metallization portion 102b. The plurality of pillar interconnects 105 comprise a plurality of pillar interconnects 105a, a plurality of pillar interconnects 105b and a plurality of pillar interconnects 105c. As mentioned above, the plurality of pillar interconnects 105 may have different widths and/or diameters. Moreover, the plurality of pillar interconnects 105 may be shifted, offset and/or aligned differently with different interconnects. This may be due to the fabrication processes that may be used.

The plurality of pillar interconnects 105a are coupled to the plurality of metallization interconnects 121a of the metallization portion 102a. The plurality of pillar interconnects 105a include a pillar interconnect 105aa, a pillar interconnect 105ab and a pillar interconnect 105ac. The pillar interconnect 105aa has a width and/or a diameter that is greater than a width and/or a diameter of the metallization interconnect (e.g., pad metallization interconnect) to which the pillar interconnect 105aa is coupled to and touching. The pillar interconnect 105ab has a width and/or a diameter that is less than a width and/or a diameter of the metallization interconnect (e.g., pad metallization interconnect) to which the pillar interconnect 105ab is coupled to and touching. The pillar interconnect 105ac is shifted and/or offset to the metallization interconnect (e.g., pad metallization interconnect) to which the pillar interconnect 105ac is coupled to and touching.

The plurality of pillar interconnects 105b are coupled to the plurality of metallization interconnects 121b of the metallization portion 102b. The plurality of pillar interconnects 105b include a pillar interconnect 105ba, a pillar interconnect 105bb and a pillar interconnect 105bc. The pillar interconnect 105ba is shifted and/or offset to the metallization interconnect (e.g., pad metallization interconnect) to which the pillar interconnect 105ba is coupled to and touching. The pillar interconnect 105bb has a width and/or a diameter that is greater than a width and/or a diameter of the metallization interconnect (e.g., pad metallization interconnect) to which the pillar interconnect 105bb is coupled to and touching. The pillar interconnect 105bc is shifted and/or offset to the metallization interconnect (e.g., pad metallization interconnect) to which the pillar interconnect 105bc is coupled to and touching.

The plurality of pillar interconnects 105c are coupled to the plurality of post interconnects 140. The plurality of pillar interconnects 105c include a pillar interconnect 105ca, a pillar interconnect 105cb, a pillar interconnect 105cc and a pillar interconnect 105cd. The pillar interconnect 105ca has a width and/or a diameter that is less than a width and/or a diameter of the post interconnect 140a to which the pillar interconnect 105ca is coupled to and touching. The pillar interconnect 105cb is shifted and/or offset to the post interconnect 140b to which the pillar interconnect 105cb is coupled to and touching. The pillar interconnect 105cc is centered and/or aligned to the post interconnect 140c to which the pillar interconnect 105cc is coupled to and touching. The pillar interconnect 105cc has a width and/or a diameter that is about the same as a width and/or a diameter of the post interconnect 140c to which the pillar interconnect 105cc is coupled to and touching. The pillar interconnect 105cd has a width and/or a diameter that is greater than a width and/or a diameter of the post interconnect 140d to which the pillar interconnect 105cd is coupled to and touching. In some implementations, the post interconnect 140a and the pillar interconnect 105ca may be considered as one pillar interconnect or one post interconnect. In some implementations, the post interconnect 140b and the pillar interconnect 105cb may be considered as one pillar interconnect or one post interconnect. In some implementations, the post interconnect 140c and the pillar interconnect 105cc may be considered as one pillar interconnect or one post interconnect. In some implementations, the post interconnect 140d and the pillar interconnect 105cd may be considered as one pillar interconnect or one post interconnect.

The package 300 is coupled to the board 101 through a plurality of solder interconnects 108. The plurality of solder interconnects 108 are coupled to the plurality of pillar interconnects 105 and the plurality of board interconnects 111. The package 300 provide a compact form factor with high density interconnects. The metallization portion 102a and/or the metallization portion 102b help provide high density interconnects in the package 300. This helps provide a compact package with high density interconnects.

A shield 109 may be coupled to the board 101. The shield 109 may at least partially surround the package 300. The shield 109 may laterally surround the package 300. The shield 109 may be an electromagnetic interference (EMI) shield. The shield 109 may include a metal material. The shield 109 may be coupled to the board 101 through an adhesive and/or a mechanical coupling. A stamping process may be used to form the shield 109. The shield 109 may include one or more openings. Different implementations may use a shield with different shapes and/or sizes. It is noted that the disclosure of FIG. 2 may also be applicable to the package 300 of FIG. 3.

A metallization portion (e.g., 102a, 102b) may include a redistribution portion. A plurality of metallization interconnects may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect). The above description of a metallization portion may apply to other metallization portions described in the disclosure.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 300) may be implemented in a radio frequency (RF) package. The RF package may be a radio frequency front end (RFFE) package. A package (e.g., 100, 300) may be configured to provide Wireless Fidelity (WiFi) communication and/or cellular communication (e.g., 2G, 3G, 4G, 5G, 6G). The packages (e.g., 100, 200) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Metallization Portion

In some implementations, fabricating a metallization portion includes several processes. FIGS. 4A-4C illustrate an exemplary sequence for providing or fabricating a metallization portion. In some implementations, the sequence of FIGS. 4A-4C may be used to provide or fabricate the plurality of metallization portions 102. However, the process of FIGS. 4A-4C may be used to fabricate any of the packages described in the disclosure.

It should be noted that the sequence of FIGS. 4A-4C may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

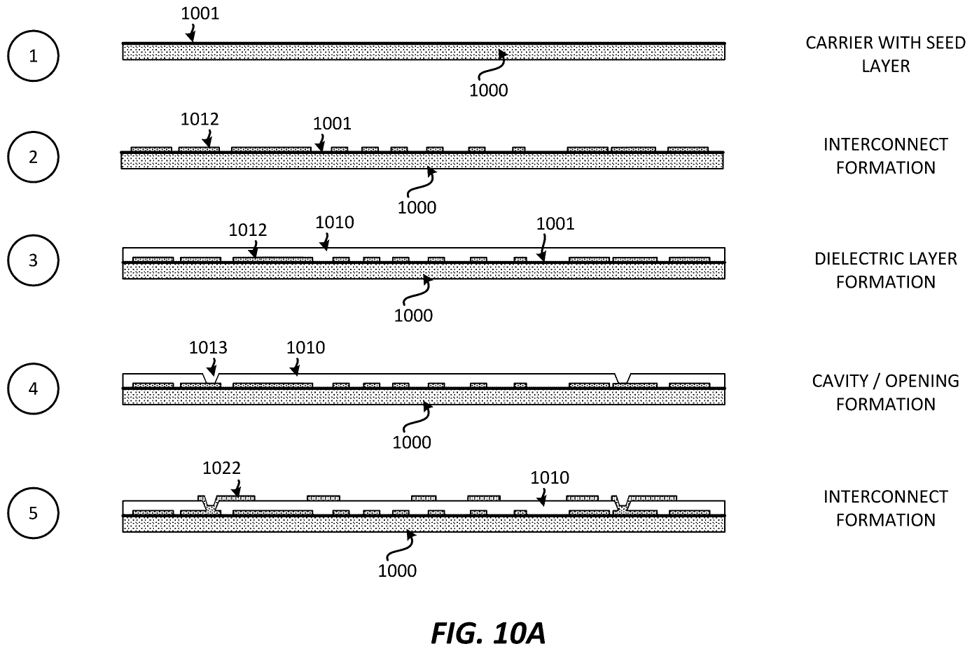

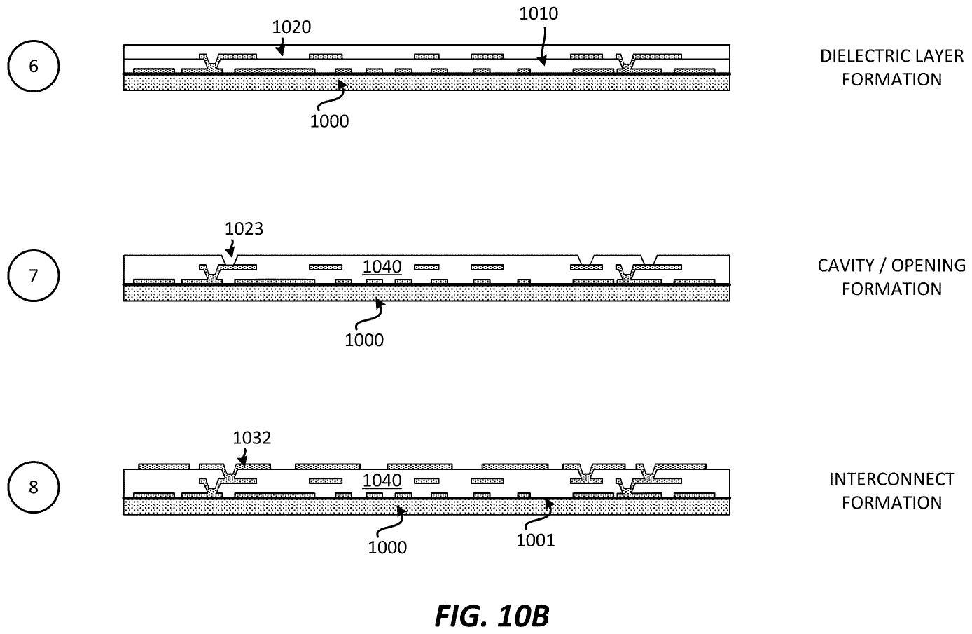

Stage 1, as shown in FIG. 4A, illustrates a state after a metallization portion 402 is provided on a first carrier 400. The metallization portion 402 includes at least one dielectric layer 120 and a plurality of metallization interconnects 121. The metallization portion 402 is coupled to the first carrier 400. FIGS. 10A-10B illustrate an example of a process for fabricating a metallization portion, which could be used to fabricate the metallization portion 402.

Stage 2 illustrates a state after a plurality of post interconnects 122 are formed and coupled to the plurality of metallization interconnects 121. A plating process may be used to form the plurality of post interconnects 122. In some implementations, the plurality of post interconnects 122 may be considered part of the plurality of metallization interconnects 121.

Stage 3 illustrates a state after a plurality of solder interconnects 130 are formed and coupled to the plurality of post interconnects 122. A pasting process and/or a solder reflow process may be used to form the plurality of solder interconnects 130.

Stage 4, as shown in FIG. 4B, illustrates a state after a second carrier 410 is coupled to the metallization portion 402. The second carrier 410 may include an adhesive. The second carrier 410 may be coupled to the plurality of solder interconnects 130, the plurality of post interconnects 122 and/or the metallization portion 402. In some implementations, an adhesive may be used to couple the second carrier 410 to the plurality of solder interconnects 130, the plurality of post interconnects 122 and/or the metallization portion 402.

Stage 5 illustrates a state after the first carrier 400 is removed. The first carrier 400 may be decoupled from the metallization portion 402. The first carrier 400 may be detached from the metallization portion 402.

Stage 6 illustrates a state after an encapsulation layer 420 is formed and coupled to the metallization portion 402. The encapsulation layer 420 may include a mold, a resin, an epoxy and/or a filler. The encapsulation layer 420 may be provided by using a compression and transfer molding process, a sheet molding process, or a liquid molding process.

Stage 7, as shown in FIG. 4C, illustrates a state after a third carrier 430 is coupled to the encapsulation layer 420. The third carrier 430 may be coupled to the encapsulation layer 420 through an adhesive.

Stage 8 illustrates a state after the second carrier 410 is removed. The second carrier 410 may be decoupled from the plurality of solder interconnects 130, the plurality of post interconnects 122 and/or the metallization portion 402. The second carrier 410 may be detached from the plurality of solder interconnects 130, the plurality of post interconnects 122 and/or the metallization portion 402.

Stage 9 illustrates a state after the third carrier 430 is removed and after a singulation process. The third carrier 430 may be decoupled from the encapsulation layer 420. The singulation process may cut the metallization portion 402 into a plurality of metallization portions 102. The plurality of metallization portions 102 may include a metallization portion 102a and a metallization portion 102b. A mechanical process (e.g., saw process) may be used to singulate the metallization portion 402 into a plurality of metallization portions 102. The plurality of metallization portion 102a may include at least one dielectric layer 120a, a plurality of metallization interconnects 121a, an encapsulation layer 420a, a plurality of post interconnects 122a and/or a plurality of solder interconnects 130a. The plurality of metallization portion 102b may include at least one dielectric layer 120b, a plurality of metallization interconnects 121b, an encapsulation layer 420b, a plurality of post interconnects 122b and/or a plurality of solder interconnects 130b.

### Exemplary Flow Diagram of a Method for Fabricating a Metallization Portion

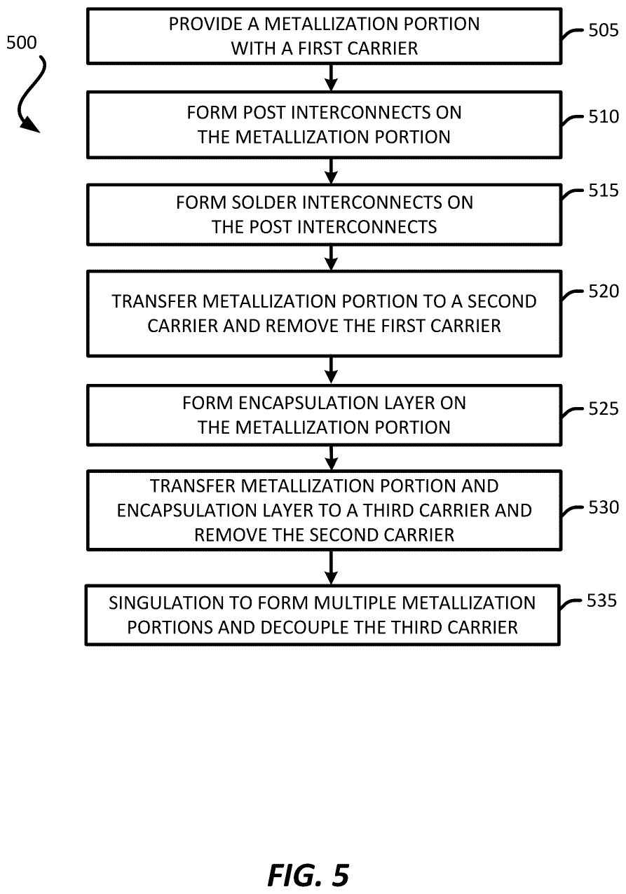

In some implementations, fabricating a metallization portion includes several processes. FIG. 5 illustrates an exemplary flow diagram of a method 500 for providing or fabricating a metallization portion. In some implementations, the method 500 of FIG. 5 may be used to provide or fabricate the plurality of metallization portions 102 described in the disclosure. However, the method 500 may be used to provide or fabricate any of the metallization portions described in the disclosure.

It should be noted that the method 500 of FIG. 5 may combine one or more processes in order to simplify and/or clarify the method for providing or fabricating a metallization portion. In some implementations, the order of the processes may be changed or modified.

The method provides (at 505) a metallization portion and a first carrier. Stage 1 of FIG. 4A, illustrates and describes an example of a state after a metallization portion 402 is provided on a first carrier 400. The metallization portion 402 includes at least one dielectric layer 120 and a plurality of metallization interconnects 121. The metallization portion 402 is coupled to the first carrier 400. FIGS. 10A-10B illustrate an example of a process for fabricating a metallization portion, which could be used to fabricate the metallization portion 402.

The method forms (at 510) a plurality of post interconnects that are coupled to the metallization portion. Stage 2 of FIG. 4A, illustrates and describes an example of a state after a plurality of post interconnects 122 are formed and coupled to the plurality of metallization interconnects 121. A plating process may be used to form the plurality of post interconnects 122.

The method forms (at 515) a plurality of solder interconnects that are coupled to the plurality of post interconnects. Stage 3 of FIG. 4A, illustrates and describes an example of a state after a plurality of solder interconnects 130 are formed and coupled to the plurality of post interconnects 122. A pasting process and/or a solder reflow process may be used to form the plurality of solder interconnects 130.

The method transfers (at 520) the metallization portion to a second carrier and removes the first carrier. Stage 4 of FIG. 4B, illustrates and describes an example of a state after a second carrier 410 is coupled to the metallization portion 402. The second carrier 410 may be coupled to the plurality of solder interconnects 130, the plurality of post interconnects 122 and/or the metallization portion 402. In some implementations, an adhesive may be used to couple the second carrier 410 to the plurality of solder interconnects 130, the plurality of post interconnects 122 and/or the metallization portion 402. Stage 5 of FIG. 4B, illustrates and describes an example of a state after the first carrier 400 is removed. The first carrier 400 may be decoupled from the metallization portion 402. The first carrier 400 may be detached from the metallization portion 402.

The method forms (at 525) an encapsulation layer that is coupled to the metallization portion. Stage 6 of FIG. 4B, illustrates and describes an example of a state after an encapsulation layer 420 is formed and coupled to the metallization portion 402. The encapsulation layer 420 may include a mold, a resin, an epoxy and/or a filler. The encapsulation layer 420 may be provided by using a compression and transfer molding process, a sheet molding process, or a liquid molding process.

The method transfers (at 530) the metallization portion to a third carrier and removes the second carrier. Stage 7 of FIG. 4C, illustrates and describes an example of a state after a third carrier 430 is coupled to the encapsulation layer 420. The third carrier 430 may be coupled to the encapsulation layer 420 through an adhesive. Stage 8 of FIG. 4C, illustrates and describes an example of a state after the second carrier 410 is removed. The second carrier 410 may be decoupled from the plurality of solder interconnects 130, the plurality of post interconnects 122 and/or the metallization portion 402. The second carrier 410 may be detached from the plurality of solder interconnects 130, the plurality of post interconnects 122 and/or the metallization portion 402.

The method singulates (at 535) the metallization portion and/or remove (at 535) the third carrier. Stage 9 of FIG. 4C, illustrates and describes an example of a state after the third carrier 430 is removed and after a singulation process. The third carrier 430 may be decoupled from the encapsulation layer 420. The singulation process may cut the metallization portion 402 into a plurality of metallization portions 102. The plurality of metallization portions 102 may include a metallization portion 102a and a metallization portion 102b. A mechanical process (e.g., saw process) may be used to singulate the metallization portion 402 into a plurality of metallization portions 102.

### Exemplary Sequence for Fabricating a Package Comprising an Integrated Device and Metallization Portions

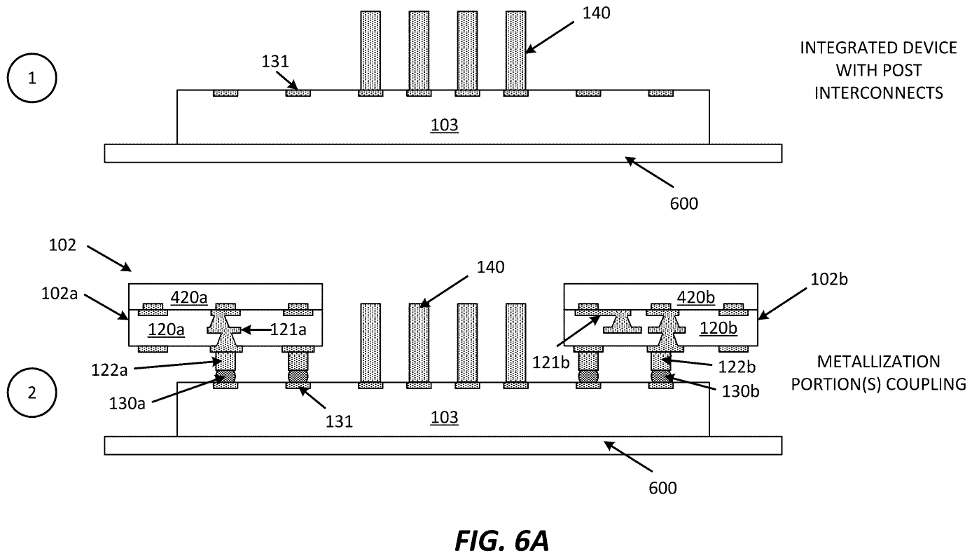

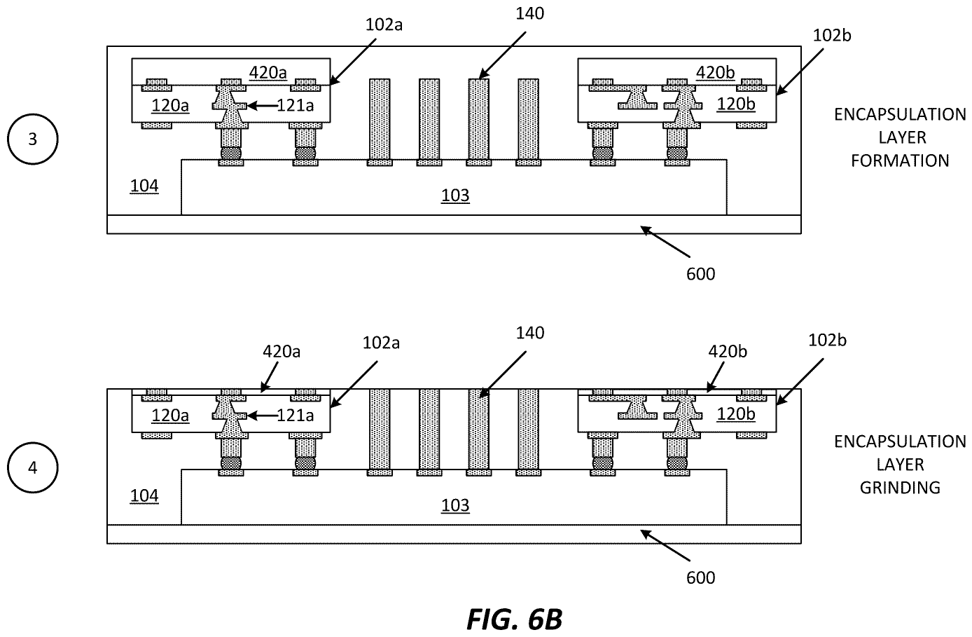

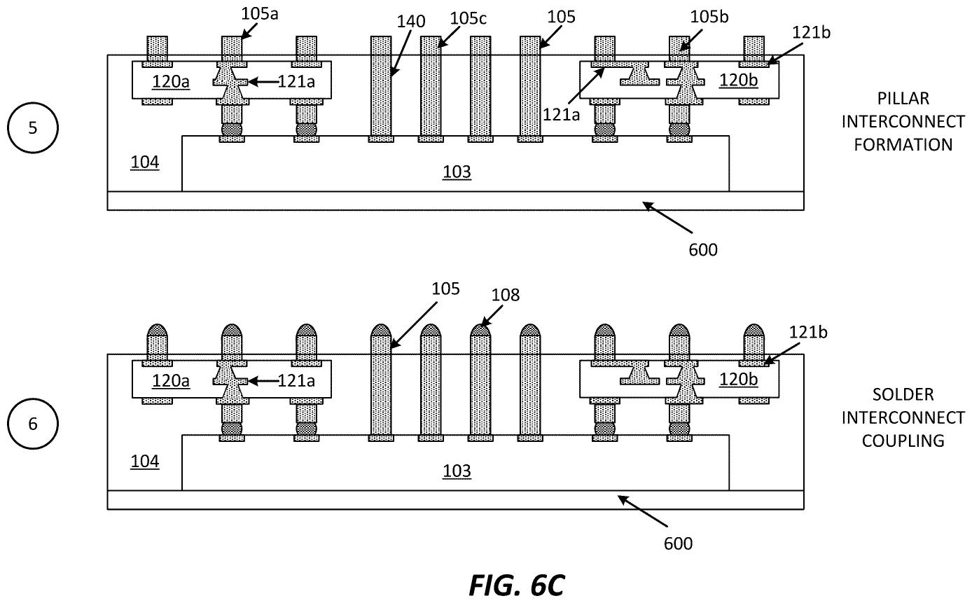

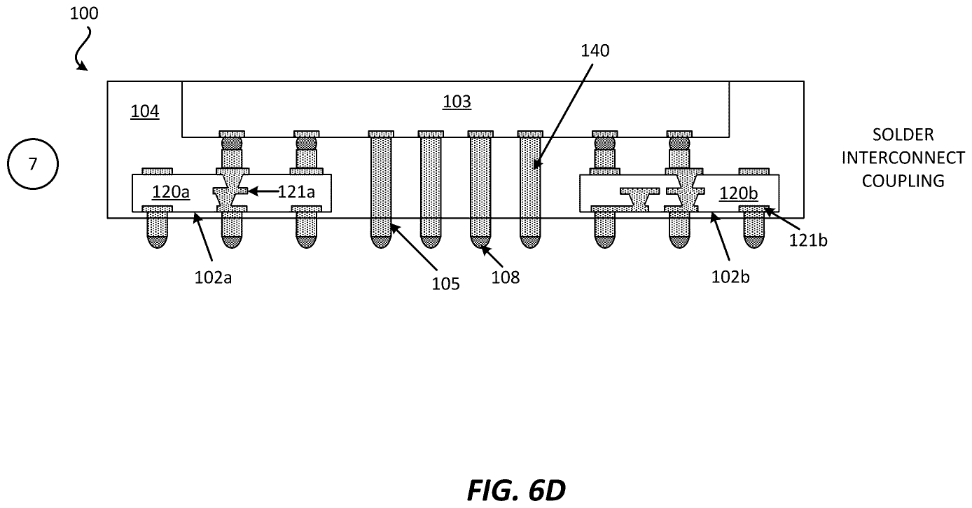

In some implementations, fabricating a package includes several processes. FIGS. 6A-6D illustrate an exemplary sequence for providing or fabricating a package. In some implementations, the sequence of FIGS. 6A-6D may be used to provide or fabricate the package 100. However, the process of FIGS. 6A-6D may be used to fabricate any of the packages described in the disclosure.

It should be noted that the sequence of FIGS. 6A-6D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 6A, illustrates a state after an integrated device 103 is provided on a carrier 600. The integrated device 103 may be coupled to the carrier 600 through an adhesive. The integrated device 103 includes a plurality of pad interconnects 131. A plurality of post interconnects 140 may be coupled to the integrated device 103. The plurality of post interconnects 140 may be coupled to and touching the plurality of pad interconnects 131 of the integrated device 103.

Stage 2 illustrates a state after a plurality of metallization portions 102 are coupled to the integrated device 103. The plurality of metallization portions 102 may include a metallization portion 102a (e.g., first metallization portion) and a metallization portion 102b (e.g., second metallization portion). A solder reflow process may be used to couple the plurality of metallization portions 102 to the integrated device 103. FIGS.-4C illustrate an example of a process that can be used to fabricate the metallization portion 102a and/or the metallization portion 102b.

The metallization portion 102a includes at least one dielectric layer 120a and a plurality of metallization interconnects 121a. A plurality of post interconnects 122a may be coupled to the plurality of metallization interconnects 121a. The plurality of post interconnects 122a may be considered part of the metallization interconnects 121a. An encapsulation layer 420a is coupled to the metallization portion 102a. In some implementations, the encapsulation layer 420a may be considered part of the metallization portion 102a. The metallization portion 102a is coupled to the integrated device 103 through the plurality of post interconnects 122a and/or the plurality of solder interconnects 130a. The plurality of solder interconnects 130a may be coupled to and touch the plurality of pad interconnects 131 and the plurality of post interconnects 122a.

The metallization portion 102b includes at least one dielectric layer 120b and a plurality of metallization interconnects 121b. A plurality of post interconnects 122b may be coupled to the plurality of metallization interconnects 121b. The plurality of post interconnects 122b may be considered part of the metallization interconnects 121b. An encapsulation layer 420b is coupled to the metallization portion 102b. In some implementations, the encapsulation layer 420b may be considered part of the metallization portion 102b. The metallization portion 102b is coupled to the integrated device 103 through the plurality of post interconnects 122b and/or the plurality of solder interconnects 130b. The plurality of solder interconnects 130b may be coupled to and touch the plurality of pad interconnects 131 and the plurality of post interconnects 122b.

Stage 3, as shown in FIG. 6B, illustrates a state after an encapsulation layer 104 is formed. The encapsulation layer 104 may be coupled to the carrier 600, the integrated device 103, the plurality of post interconnects 140, the metallization portion 102a, the encapsulation layer 420a, the metallization portion 102b and/or the encapsulation layer 420b. The encapsulation layer 104 may at least partially encapsulate the integrated device 103, the plurality of post interconnects 140, the metallization portion 102a, the encapsulation layer 420a, the metallization portion 102b and/or the encapsulation layer 420b. The encapsulation layer 104 may include a mold, a resin, an epoxy and/or a filler. The encapsulation layer 104 may be provided by using a compression and transfer molding process, a sheet molding process, or a liquid molding process. The encapsulation layer 104 may be similar or different from the encapsulation layer 402a and/or the encapsulation layer 420b. In some implementations, the encapsulation layer 402a and/or the encapsulation layer 420b may be considered part of the encapsulation layer 104.

Stage 4 illustrates a state after portions of the encapsulation layer 104 are removed. A grinding process may be used to planarize the encapsulation layer 104 and/or remove portions of the encapsulation layer 104. In some implementations, the grinding process may also remove portions of the encapsulation layer 420a and/or portions of the encapsulation layer 420b.

Stage 5, as shown in FIG. 6C, illustrates a state after a plurality of pillar interconnects 105 are coupled to the plurality of post interconnects 140, the metallization portion 102a and/or the metallization portion 102b. A plating process may be used to form the plurality of pillar interconnects 105. The plurality of pillar interconnects 105 may include a plurality of pillar interconnects 105a, a plurality of pillar interconnects 105b and a plurality of pillar interconnects 105c. The plurality of pillar interconnects 105a may be coupled to the plurality of metallization interconnects 121a. The plurality of pillar interconnects 105b may be coupled to the plurality of metallization interconnects 121b. The plurality of pillar interconnects 105c may be coupled to the plurality of post interconnects 140. The plurality of pillar interconnects 105 may have different sizes, widths, diameters, offsets, alignment with other interconnects, as described above in FIG. 1 and FIG. 3.

Stage 6 illustrates a state after a plurality of solder interconnects 108 are formed and coupled to the plurality of pillar interconnects 105. A pasting process and/or solder reflow process may be used to form and couple the plurality of solder interconnects 108 to the plurality of pillar interconnects.

Stage 7, as shown in FIG. 6D, illustrates a state after the carrier 600 is removed. The carrier 600 may be decoupled from the integrated device 103 and/or the encapsulation layer 104. Stage 7 may illustrates the package 100.

### Exemplary Flow Diagram of a Method for Fabricating a Package Comprising an Integrated Device and Metallization Portions

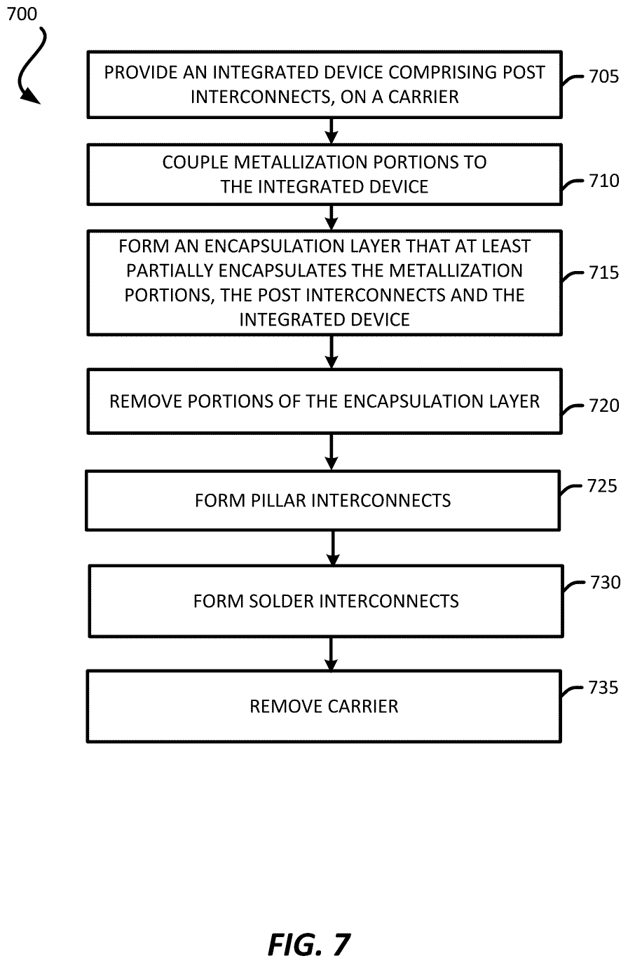

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 100 described in the disclosure. However, the method 700 may be used to provide or fabricate any of the packages described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a carrier and an integrated device. A plurality of post interconnects may be coupled to the integrated device. Stage 1 of FIG. 6A, illustrates and describes an example of a state after an integrated device 103 is provided on a carrier 600. The integrated device 103 includes a plurality of pad interconnects 131. A plurality of post interconnects 140 may be coupled to the integrated device 103. The plurality of post interconnects 140 may be coupled to and touching the plurality of pad interconnects 131 of the integrated device 103.

The method couples (at 710) a plurality of metallization portions to the integrated device. Stage 2 of FIG. 6A, illustrates and describes an example of a state after a plurality of metallization portions 102 are coupled to the integrated device 103. The plurality of metallization portions 102 may include a metallization portion 102a (e.g., first metallization portion) and a metallization portion 102b (e.g., second metallization portion). A solder reflow process may be used to couple the plurality of metallization portions 102 to the integrated device 103. FIGS. 4A-4C illustrate an example of a process that can be used to fabricate the metallization portion 102a and/or the metallization portion 102b.

The metallization portion 102a includes at least one dielectric layer 120a and a plurality of metallization interconnects 121a. A plurality of post interconnects 122a may be coupled to the plurality of metallization interconnects 121a. The plurality of post interconnects 122a may be considered part of the metallization interconnects 121a. An encapsulation layer 420a is coupled to the metallization portion 102a. The metallization portion 102a is coupled to the integrated device 103 through the plurality of post interconnects 122a and/or the plurality of solder interconnects 130a. The plurality of solder interconnects 130a may be coupled to and touch the plurality of pad interconnects 131 and the plurality of post interconnects 122a.

The metallization portion 102b includes at least one dielectric layer 120b and a plurality of metallization interconnects 121b. A plurality of post interconnects 122b may be coupled to the plurality of metallization interconnects 121b. The plurality of post interconnects 122b may be considered part of the metallization interconnects 121b. An encapsulation layer 420b is coupled to the metallization portion 102b. The metallization portion 102b is coupled to the integrated device 103 through the plurality of post interconnects 122b and/or the plurality of solder interconnects 130b. The plurality of solder interconnects 130b may be coupled to and touch the plurality of pad interconnects 131 and the plurality of post interconnects 122b.

The method forms (at 715) an encapsulation layer that at least partially encapsulates the integrated device, the plurality of post interconnects and the plurality of metallization portions. Stage 3 of FIG. 6B, illustrates and describes an example of a state after an encapsulation layer 104 is formed. The encapsulation layer 104 may be coupled to the carrier 600, the integrated device 103, the plurality of post interconnects 140, the metallization portion 102a, the encapsulation layer 420a, the metallization portion 102b and/or the encapsulation layer 420b. The encapsulation layer 104 may at least partially encapsulate the integrated device 103, the plurality of post interconnects 140, the metallization portion 102a, the encapsulation layer 420a, the metallization portion 102b and/or the encapsulation layer 420b. The encapsulation layer 104 may include a mold, a resin, an epoxy and/or a filler. The encapsulation layer 104 may be provided by using a compression and transfer molding process, a sheet molding process, or a liquid molding process. The encapsulation layer 104 may be similar or different from the encapsulation layer 402a and/or the encapsulation layer 420b.

The method removes (at 720) a portion of the encapsulation layer. Stage 4 of FIG. 6B, illustrates and describes an example of a state after portions of the encapsulation layer 104 are removed. A grinding process may be used to planarize the encapsulation layer 104 and/or remove portions of the encapsulation layer 104. In some implementations, the grinding process may also remove portions of the encapsulation layer 420a and/or portions of the encapsulation layer 420b.

The method forms (at 725) a plurality of pillar interconnects. Stage 5 of FIG. 6C, illustrates and describes an example of a state after a plurality of pillar interconnects 105 are coupled to the plurality of post interconnects 140, the metallization portion 102a and/or the metallization portion 102b. A plating process may be used to form the plurality of pillar interconnects 105. The plurality of pillar interconnects 105 may include a plurality of pillar interconnects 105a, a plurality of pillar interconnects 105b and a plurality of pillar interconnects 105c. The plurality of pillar interconnects 105a may be coupled to the plurality of metallization interconnects 121a. The plurality of pillar interconnects 105b may be coupled to the plurality of metallization interconnects 121b. The plurality of pillar interconnects 105c may be coupled to the plurality of post interconnects 140. The plurality of pillar interconnects 105 may have different sizes, widths, diameters, offsets, alignment with other interconnects, as described above in FIG. 1 and FIG. 3.

The method forms (at 730) a plurality of solder interconnects. Stage 6 of FIG. 6C, illustrates and describes an example of a state after a plurality of solder interconnects 108 are formed and coupled to the plurality of pillar interconnects 105. A pasting process and/or solder reflow process may be used to form and couple the plurality of solder interconnects 108 to the plurality of pillar interconnects.

The method removes (at 735) the carrier. Stage 7 of FIG. 6D, illustrates and describes an example of a state after the carrier 600 is removed. The carrier 600 may be decoupled from the integrated device 103 and/or the encapsulation layer 104.

### Exemplary Sequence for Fabricating a Substrate

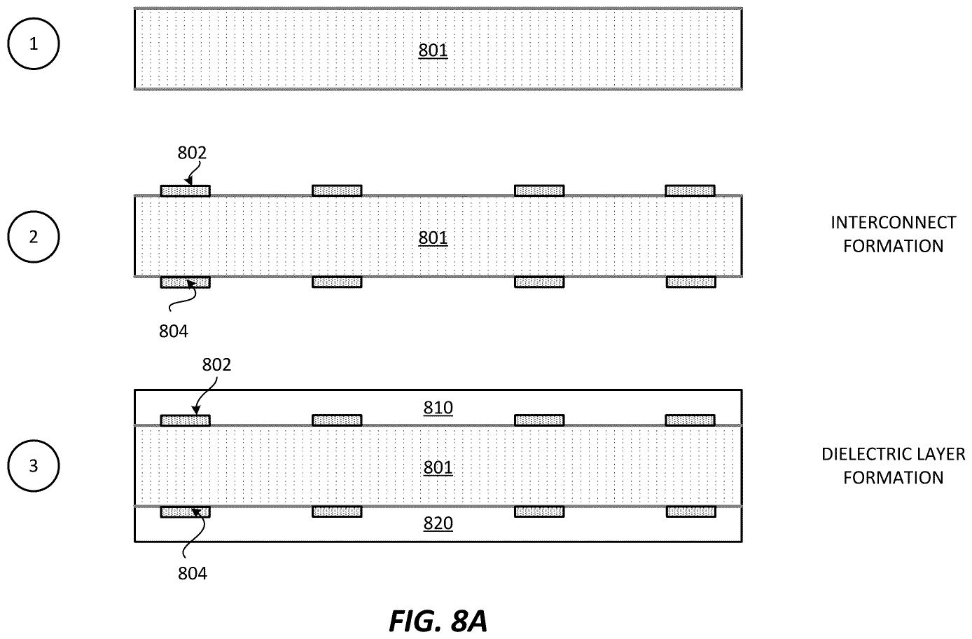

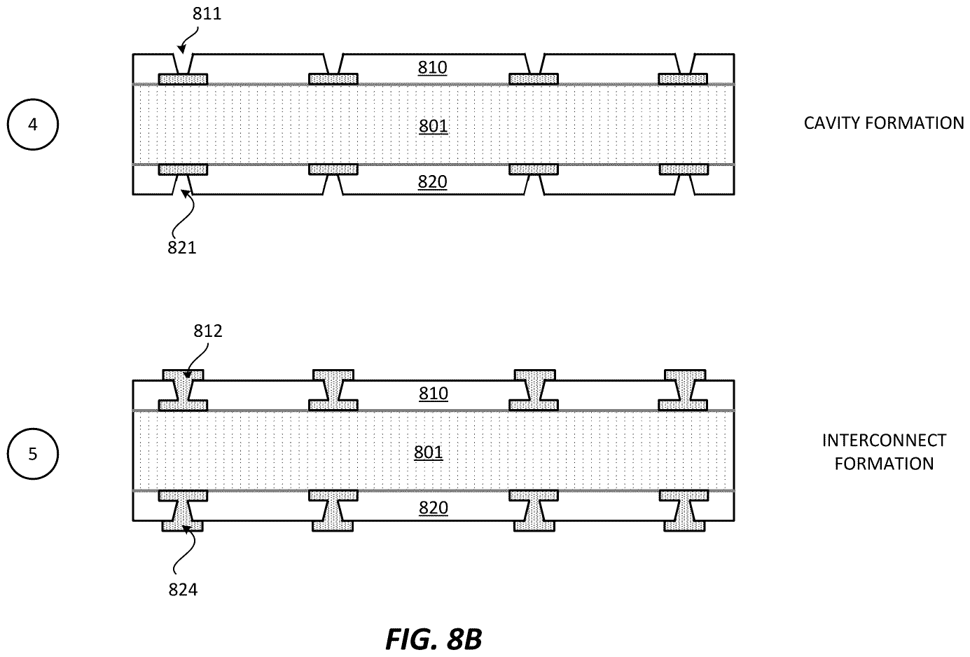

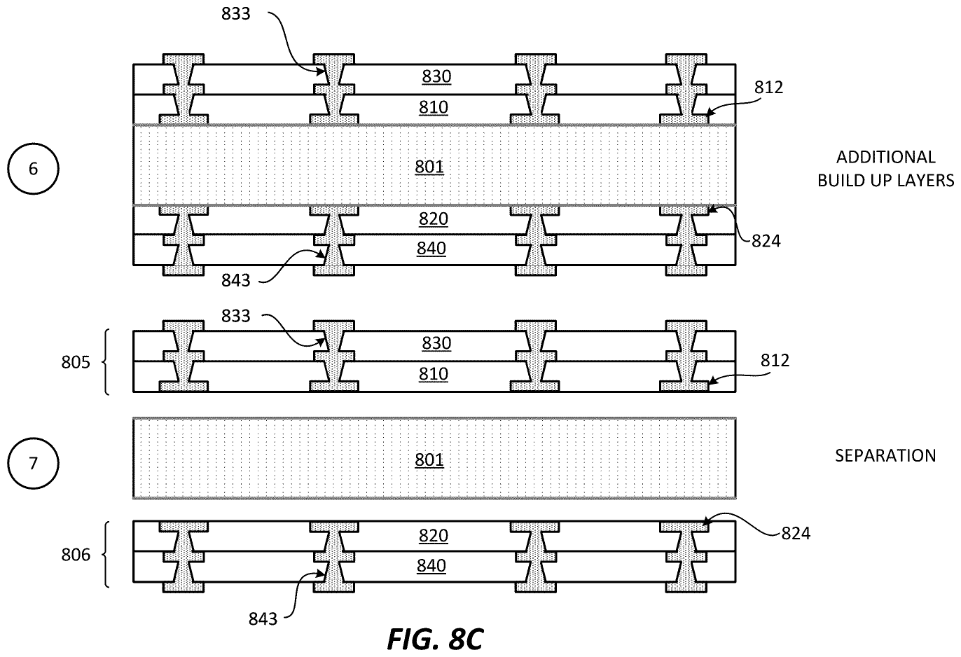

In some implementations, the package 100 and/or the package 300 may be coupled to a substrate. In some implementations, fabricating a substrate includes several processes. FIGS. 8A-8C illustrate an exemplary sequence for providing or fabricating a substrate. In some implementations, the sequence of FIGS. 8A-8C may be used to provide or fabricate a laminated substrate. The laminate substrate that is provided in FIGS. 8A-8C may be coupled to the package 100 or the package 300.

It should be noted that the sequence of FIGS. 8A-8C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 8A, illustrates a state after a carrier 801 is provided. The carrier 801 may include a core layer. The core layer may include seed layers on surfaces of the core layer.

Stage 2 illustrates a state after a plurality of interconnects 802 and a plurality of interconnects 804 are formed. The plurality of interconnects 802 may be coupled to a first surface (e.g., top surface) of the carrier 801. The plurality of interconnects 804 may be coupled to a second surface (e.g., bottom surface) of the carrier 801. A plating process may be used to form the plurality of interconnects 802 and the plurality of interconnects 804. The plurality of interconnects 802 may be formed on a first seed layer of the carrier 801. The plurality of interconnects 804 may be formed on a second seed layer of the carrier 801.

Stage 3 illustrates a state after a dielectric layer 810 and a dielectric layer 820 are provided. The dielectric layer 810 may be coupled to the first surface of the carrier 801. The dielectric layer 820 may be coupled to the second surface of the carrier 801. A deposition and/or a lamination process may be used to form the dielectric layer 810 and/or the dielectric layer 820. The dielectric layer 810 and/or the dielectric layer 820 may include prepreg, polymer and/or Ajinomoto Build-up Film (ABF).

Stage 4 of FIG. 8B, illustrates a state after a plurality of cavities 811 are formed in the dielectric layer 810, and a plurality of cavities 821 are formed in the dielectric layer 820. An exposure and development process may be used to form the plurality of cavities 811 in the dielectric layer 810 and the plurality of cavities 821 in the dielectric layer 820. Different implementations may use different processes to form the plurality of cavities.

Stage 5 illustrates a state after a plurality of interconnects 812 are formed in the dielectric layer 810, and a plurality of interconnects 824 are formed in the dielectric layer 820. The plurality of interconnects 812 may be coupled to the plurality of interconnects 802. The plurality of interconnects 824 may be coupled to the plurality of interconnects 804. A plating process may be used to form the plurality of interconnects 812 and/or the plurality of interconnects 824.

Stage 6, as shown in FIG. 8C, illustrates a state after additional build up layers are formed. For example, stage 6 illustrates a state after additional dielectric layers and additional interconnects are formed. For example, a dielectric layer 830 may be formed and coupled to the dielectric layer 810. A dielectric layer 840 may be formed and coupled to the dielectric layer 820. A lamination process and/or a deposition process may be used to form the dielectric layer 830 and the dielectric layer 840.

Stage 6 further illustrates a state after a plurality of interconnects 833 are formed in and over the dielectric layer 830, and after a plurality of interconnects 843 are formed in and over the dielectric layer 840. The plurality of 833 may be coupled to the plurality of interconnects 812. The plurality of 843 may be coupled to the plurality of interconnects 824. A plurality of cavities may be formed in the dielectric layer 830 and the dielectric layer 840 in a similar manner as described for forming a plurality of cavities in Stage 4 of FIG. 8B. The plurality of interconnects 833 and the plurality of interconnects 843 may be formed in a similar manner as described for fabricating a plurality of interconnects in Stage 5 of FIG. 8B.

Stage 7 illustrates a state after separation of the dielectric layers from the carrier 801. For example, the dielectric layer 810, the dielectric layer 830, the plurality of interconnects 802, the plurality of interconnects 812 and the plurality of interconnects 833 are separated from the carrier 801 to form a substrate 805 (e.g., coreless substrate). In another example, the dielectric layer 820, the dielectric layer 840, the plurality of interconnects 804, the plurality of interconnects 824 and the plurality of interconnects 843 are separated from the carrier 801 to form a substrate 806 (e.g., coreless substrate).

The substrate 805 and/or the substrate 806 may be used instead of the substrate 101, in the package 100 and/or the package 200. In some implementations, once separation occurs, one or more polyimide dielectric layers may be formed on surface(s) of the substrate 805 and/or the substrate 806.

### Exemplary Flow Diagram of a Method for Fabricating a Substrate

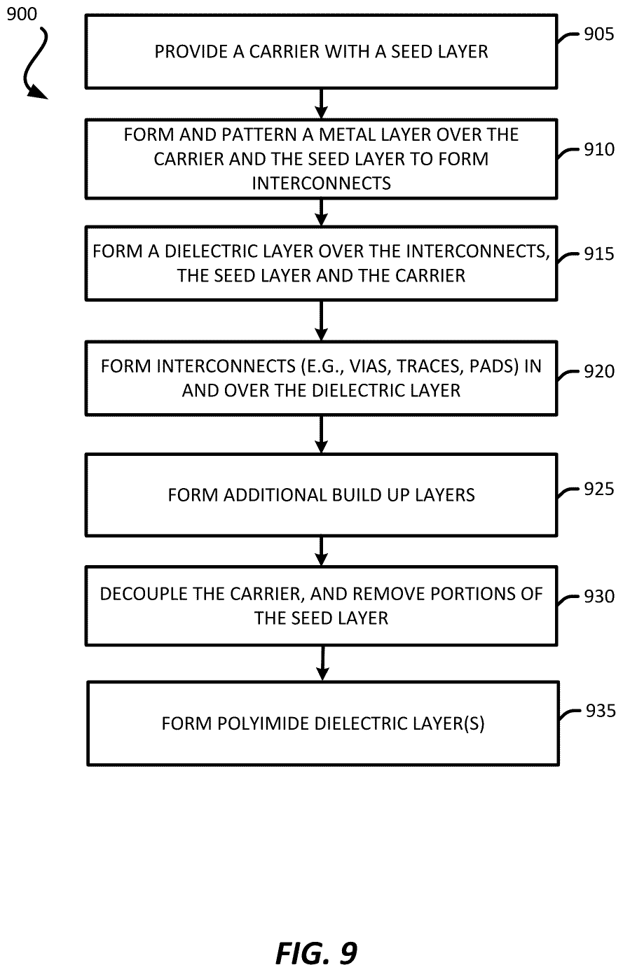

In some implementations, fabricating an substrate includes several processes. FIG. 9 illustrates an exemplary flow diagram of a method 900 for providing or fabricating a substrate. In some implementations, the method 900 of FIG. 9 may be used to provide or fabricate a substrate.

It should be noted that the method 900 of FIG. 9 may combine one or more processes in order to simplify and/or clarify the method for providing or fabricating a substrate. In some implementations, the order of the processes may be changed or modified.

The method provides (at 905) a carrier. The carrier may include seed layers. Stage 1 of FIG. 8A, illustrates and describes an example of a state after a carrier 801 is provided. The carrier 801 may include a core layer. The core layer may include seed layers on surfaces of the core layer.

The method forms (at 910) a plurality of interconnects on the carrier and/or the seed layer(s). Stage 2 of FIG. 8A, illustrates and describes an example of a state after a plurality of interconnects 802 and a plurality of interconnects 804 are formed. The plurality of interconnects 802 may be coupled to a first surface (e.g., top surface) of the carrier 801. The plurality of interconnects 804 may be coupled to a second surface (e.g., bottom surface) of the carrier 801. A plating process may be used to form the plurality of interconnects 802 and the plurality of interconnects 804. The plurality of interconnects 802 may be formed on a first seed layer of the carrier 801. The plurality of interconnects 804 may be formed on a second seed layer of the carrier 801.

The method forms (at 915) at least one dielectric layer over the plurality of interconnects, the seed layer(s) and/or the carrier. Stage 3 of FIG. 8A, illustrates and describes an example of a state after a dielectric layer 810 and a dielectric layer 820 are provided. The dielectric layer 810 may be coupled to the first surface of the carrier 801. The dielectric layer 820 may be coupled to the second surface of the carrier 801. A deposition and/or a lamination process may be used to form the dielectric layer 810 and/or the dielectric layer 820. The dielectric layer 810 and/or the dielectric layer 820 may include prepreg, polymer and/or Ajinomoto Build-up Film (ABF).

Forming the plurality of interconnects may include forming a plurality of cavities in the dielectric layer(s). Stage 4 of FIG. 8B, illustrates and describes an example of a state after a plurality of cavities 811 are formed in the dielectric layer 810, and a plurality of cavities 821 are formed in the dielectric layer 820. An exposure and development process may be used to form the plurality of cavities 811 in the dielectric layer 810 and the plurality of cavities 821 in the dielectric layer 820. Different implementations may use different processes to form the plurality of cavities.

Stage 5 of FIG. 8B, illustrates and describes an example of a state after a plurality of interconnects 812 are formed in the dielectric layer 810, and a plurality of interconnects 824 are formed in the dielectric layer 820. The plurality of interconnects 812 may be coupled to the plurality of interconnects 802. The plurality of interconnects 824 may be coupled to the plurality of interconnects 804. A plating process may be used to form the plurality of interconnects 812 and/or the plurality of interconnects 824.

The method forms (at 925) additional build up layers. Stage 6 of FIG. 8C, illustrates and describes an example of a state after additional build up layers are formed. For example, stage 6 illustrates a state after additional dielectric layers and additional interconnects are formed. For example, a dielectric layer 830 may be formed and coupled to the dielectric layer 810. A dielectric layer 840 may be formed and coupled to the dielectric layer 820. A lamination process and/or a deposition process may be used to form the dielectric layer 830 and the dielectric layer 840.

Stage 6 of FIG. 8C, further illustrates and describes an example of a state after a plurality of interconnects 833 are formed in and over the dielectric layer 830, and after a plurality of interconnects 843 are formed in and over the dielectric layer 840. The plurality of 833 may be coupled to the plurality of interconnects 812. The plurality of 843 may be coupled to the plurality of interconnects 824. A plurality of cavities may be formed in the dielectric layer 830 and the dielectric layer 840 in a similar manner as described for forming a plurality of cavities in Stage 4 of FIG. 8B. The plurality of interconnects 833 and the plurality of interconnects 843 may be formed in a similar manner as described for fabricating a plurality of interconnects in Stage 5 of FIG. 8B.

The method decouples (at 930) the carrier from the dielectric layers. The method may further remove portions of the seed layer(s). Stage 7 of FIG. 8C, illustrates and describes an example of a state after separation of the dielectric layers from the carrier 801. For example, the dielectric layer 810, the dielectric layer 830, the plurality of interconnects 802, the plurality of interconnects 812 and the plurality of interconnects 833 are separated from the carrier 801 to form a substrate 805 (e.g., coreless substrate). In another example, the dielectric layer 820, the dielectric layer 840, the plurality of interconnects 804, the plurality of interconnects 824 and the plurality of interconnects 843 are separated from the carrier 801 to form a substrate 806 (e.g., coreless substrate). The substrate 805 and/or the substrate 806 may be used instead of the substrate 101, in the package 100 and/or the package 200.

The method may further form (at 935) polyimide dielectric layer(s) on the substrate. In some implementations, once separation occurs, one or more polyimide dielectric layers may be formed on surface(s) of the substrate 805 and/or the substrate 806.

### Exemplary Sequence for Fabricating a Metallization Portion

In some implementations, fabricating a metallization portion includes several processes. FIGS. 10A-10B illustrate an exemplary sequence for providing or fabricating a metallization portion. In some implementations, the sequence of FIGS. 10A-10B may be used to provide or fabricate the plurality of metallization portions 102. However, the process of FIGS. 10A-10B may be used to fabricate any of the metallization portions described in the disclosure.

It should be noted that the sequence of FIGS. 10A-10B may combine one or more stages in order to simplify and/or clarify the sequence for providing or fabricating a metallization portion. A metallization portion may include a redistribution portion. In some implementations, the order of the processes may be changed or modified. In some implementations, one or more of processes may be replaced or substituted without departing from the scope of the disclosure.

Stage 1, as shown in FIG. 10A, illustrates a state after a carrier 1000 is provided. A seed layer 1001 may be located over the carrier 1000. The carrier 1000 may be replaced with other components and/or materials.

Stage 2 illustrates a state after a plurality of interconnects 1012 are formed. The interconnects 1012 may be located over the seed layer 1001. A lithography process, a plating process, a strip process and/or an etching process may be used to form the plurality of interconnects 1012.

Stage 3 illustrates a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

Stage 4 illustrates a state after a plurality of cavities 1013 is formed in the dielectric layer 1010. The plurality of cavities 1013 may be formed using an etching process (e.g., photo etching process), a laser process, an exposure process and/or a development process.

Stage 5 illustrates a state after interconnects 1022 are formed in and over the dielectric layer 1010, including in and over the plurality of cavities 1013. For example, a via, pad and/or traces may be formed. A lithography process, a plating process, a strip process and/or an etching process may be used to form the interconnects.

Stage 6, as shown in FIG. 10B, illustrates a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

Stage 7, illustrates a state after a plurality of cavities 1023 is formed in the dielectric layer 1040. The dielectric layer 1040 may represent the dielectric layer 1010 and/or the dielectric layer 1020. The plurality of cavities 1023 may be formed using an etching process (e.g., photo etching process), a laser process, an exposure process and/or a development process.

Stage 8 illustrates a state after interconnects 1032 are formed in and over the dielectric layer 1040, including in and over the plurality of cavities 1023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

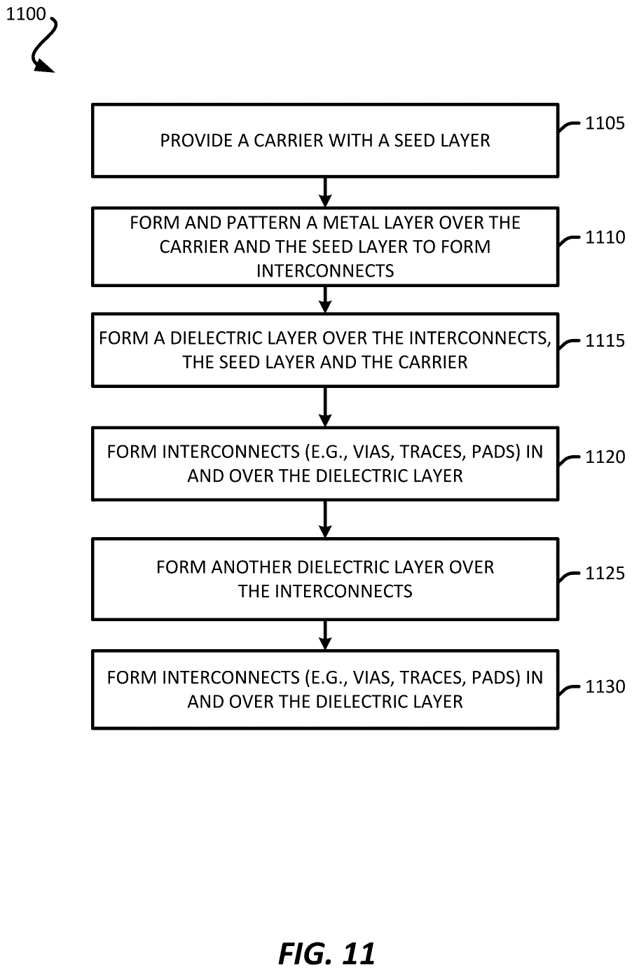

In some implementations, fabricating a metallization portion includes several processes. FIG. 11 illustrates an exemplary flow diagram of a method 1100 for providing or fabricating a metallization portion. In some implementations, the method 1100 of FIG. 11 may be used to provide or fabricate any of the metallization portions of the disclosure. For example, the method 1100 of FIG. 11 may be used to fabricate the plurality of metallization portions 102.

It should be noted that the method 1100 of FIG. 11 may combine one or more processes in order to simplify and/or clarify the method for providing or fabricating a metallization portion. A metallization portion may include a redistribution portion. In some implementations, the order of the processes may be changed or modified.

The method provides (at 1105) a carrier with a seed layer. Stage 1 of FIG. 10A, illustrates and describes an example of a state after a carrier 1000 is provided. A seed layer 1001 may be located over the carrier 1000. The carrier 1000 may be replaced with other components and/or materials.

The method forms and patterns (at 1110) a plurality of interconnects. Stage 2 of FIG. 10A, illustrates and describes an example of a state after a plurality of interconnects 1012 are formed. The interconnects 1012 may be located over the seed layer 1001. A lithography process, a plating process, a strip process and/or an etching process may be used to form the plurality of interconnects 1012.

The method forms (at 1110) a dielectric layer. Stage 3 of FIG. 10A, illustrates and describes an example of a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

The method forms (at 1120) a plurality of interconnects. Forming a plurality of interconnects may including forming a plurality of cavities in a dielectric layer and a performing a plating process. Stage 4 of FIG. 10A, illustrates and describes an example of a state after a plurality of cavities 1013 is formed in the dielectric layer 1010. The plurality of cavities 1013 may be formed using an etching process (e.g., photo etching process), a laser process, an exposure process and/or a development process.

Stage 5 of FIG. 10A, illustrates and describes an example of a state after interconnects 1022 are formed in and over the dielectric layer 1010, including in and over the plurality of cavities 1013. For example, a via, pad and/or traces may be formed. A lithography process, a plating process, a strip process and/or an etching process may be used to form the interconnects.

The method forms (at 1125) another dielectric layer. Stage 6 of FIG. 10B, illustrates and describes an example of a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

The method forms (at 1130) a plurality of interconnects. Forming a plurality of interconnects may including forming a plurality of cavities in a dielectric layer and a performing a plating process. Stage 7 of FIG. 10B, illustrates and describes an example of a state after a plurality of cavities 1023 is formed in the dielectric layer 1040. The dielectric layer 1040 may represent the dielectric layer 1010 and/or the dielectric layer 1020. The plurality of cavities 1023 may be formed using an etching process (e.g., photo etching process), a laser process, an exposure process and/or a development process.

Stage 8 of FIG. 10B, illustrates and describes an example of a state after interconnects 1032 are formed in and over the dielectric layer 1040, including in and over the plurality of cavities 1023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

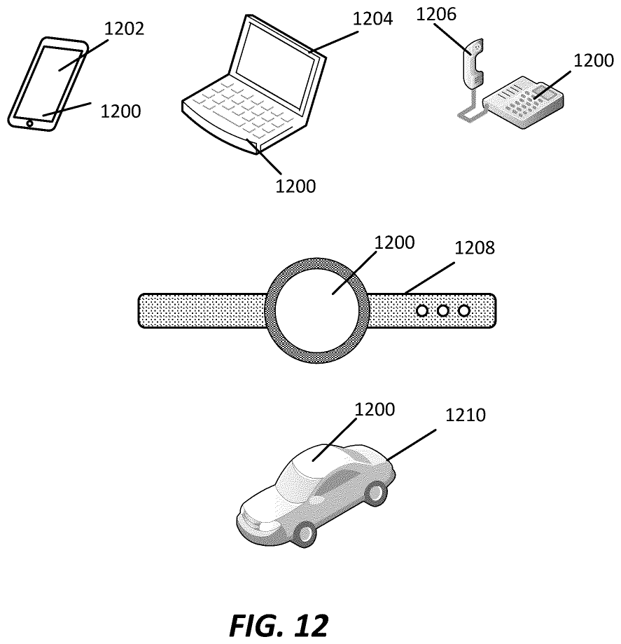

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4C, 5, 6A-6D, 7, 8A-8C, 9, 10A-10B, and 11-12 may be rearranged and/or combined into a single component, process, feature or function or embodied in several components, processes, or functions. Additional elements, components, processes, and/or functions may also be added without departing from the disclosure. It should also be noted FIGS. 1-3, 4A-4C, 5, 6A-6D, 7, 8A-8C, 9, 10A-10B, and 11-12 and its corresponding description in the present disclosure is not limited to dies and/or ICs. In some implementations, FIGS. 1-3, 4A-4C, 5, 6A-6D, 7, 8A-8C, 9, 10A-10B, and 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising an integrated device; a plurality of post interconnects coupled to the integrated device; a first metallization portion coupled to the integrated device through a first plurality of solder interconnects; a second metallization portion coupled to the integrated device through a second plurality of solder interconnects; an encapsulation layer at least partially encapsulating the integrated device, the first metallization portion, the second metallization portion, the plurality of post interconnects, the first plurality of solder interconnects and the second plurality of solder interconnects; and a plurality of pillar interconnects coupled to the first metallization portion, the second metallization portion and the plurality of post interconnects.

Aspect 2: The package of aspect 1, wherein the first metallization portion is coupled to a first plurality of pad interconnects of the integrated device through the first plurality of solder interconnects, and wherein the second metallization portion is coupled to a second plurality of pad interconnects of the integrated device through the second plurality of solder interconnects.

Aspect 3: The package of aspect 2, wherein the plurality of post interconnects are coupled to and touching a third plurality of pad interconnects of the integrated device.

Aspect 4: The package of aspects 1 through 3, wherein the plurality of post interconnects are located laterally between the first metallization portion and the second metallization portion.

Aspect 5: The package of aspects 1 through 4, wherein the first metallization portion includes a first dielectric layer and a first plurality of metallization interconnects, and wherein the second metallization portion includes a second dielectric layer and a second plurality of metallization interconnects.

Aspect 6: The package of aspect 5, wherein the plurality of pillar interconnects comprise a first plurality of pillar interconnects coupled to the first plurality of metallization interconnects of the first metallization portion; a second plurality of pillar interconnects coupled to the second plurality of metallization interconnects of the second metallization portion; and a third plurality of pillar interconnects coupled to the plurality of post interconnects.

Aspect 7: The package of aspect 6, wherein a pillar interconnect from the first plurality of pillar interconnects is coupled to, touching and misaligned with a metallization interconnect from the first plurality of metallization interconnects.

Aspect 8: The package of aspect 6, wherein a pillar interconnect from the second plurality of pillar interconnects is coupled to, touching and misaligned with a metallization interconnect from the second plurality of metallization interconnects.

Aspect 9: The package of aspect 6, wherein a pillar interconnect from the third plurality of pillar interconnects is coupled to, touching and misaligned with a post interconnect from the plurality of post interconnects.

Aspect 10: The package of aspects 1 through 9, wherein the first metallization portion partially overlaps vertically with the integrated device.

Aspect 11: The package of aspects 1 through 10, wherein the first metallization portion completely overlaps vertically with the integrated device.

Aspect 12: The package of aspects 1 through 11, wherein the first metallization portion is coupled to the integrated device through a first plurality of pillar interconnects and the first plurality of solder interconnects, wherein the second metallization portion is coupled to the integrated device through a second plurality of pillar interconnects and the second plurality of solder interconnects, wherein the first plurality of pillar interconnects and the second plurality of pillar interconnects are different from the plurality of pillar interconnects.

Aspect 13: The package of aspect 12, wherein the first plurality of pillar interconnects are part of the first metallization portion, and wherein the second plurality of pillar interconnects are part of the second metallization portion.

Aspect 14: The package of aspects 1 through 13, wherein the plurality of pillar interconnects are located outside of the encapsulation layer.

Aspect 15: The package of aspects 1 through 14, wherein the plurality of pillar interconnects include a width that is different from a width of a post interconnect from the plurality of post interconnects.

Aspect 16: The package of aspects 1 through 15, wherein the plurality of pillar interconnects include a width that is different from a width of a metallization interconnect from a plurality of metallization interconnects from the first metallization portion.

Aspect 17: The package of aspects 1 through 16 further comprising a third metallization portion coupled to the integrated device through a third plurality of solder interconnects; and a fourth metallization portion coupled to the integrated device through a fourth plurality of solder interconnects.

Aspect 18: A method for fabricating a package, comprising providing an integrated device, wherein a plurality of post interconnects are coupled to the integrated device; coupling a first metallization portion to the integrated device through a first plurality of solder interconnects; coupling a second metallization portion to the integrated device through a second plurality of solder interconnects; forming an encapsulation layer that at least partially encapsulates the integrated device, the first metallization portion, the second metallization portion, the plurality of post interconnects, the first plurality of solder interconnects and the second plurality of solder interconnects; and forming a plurality of pillar interconnects that are coupled to the first metallization portion, the second metallization portion and the plurality of post interconnects.

Aspect 19: The method of aspect 18, wherein the first metallization portion is coupled to a first plurality of pad interconnects of the integrated device through the first plurality of solder interconnects, and wherein the second metallization portion is coupled to a second plurality of pad interconnects of the integrated device through the second plurality of solder interconnects.

Aspect 20: The method of aspect 19, wherein the plurality of post interconnects are coupled to and touching a third plurality of pad interconnects of the integrated device.

Aspect 21: The package of aspects 1 through 17, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device;
a plurality of post interconnects coupled to the integrated device;
a first metallization portion coupled to the integrated device through a first plurality of solder interconnects;
a second metallization portion coupled to the integrated device through a second plurality of solder interconnects;
an encapsulation layer at least partially encapsulating the integrated device, the first metallization portion, the second metallization portion, the plurality of post interconnects, the first plurality of solder interconnects and the second plurality of solder interconnects; and
a plurality of pillar interconnects coupled to the first metallization portion, the second metallization portion and the plurality of post interconnects.

2. The package of claim 1,
wherein the first metallization portion is coupled to a first plurality of pad interconnects of the integrated device through the first plurality of solder interconnects, and
wherein the second metallization portion is coupled to a second plurality of pad interconnects of the integrated device through the second plurality of solder interconnects.

3. The package of claim 2, wherein the plurality of post interconnects are coupled to and touching a third plurality of pad interconnects of the integrated device.

4. The package of claim 1, wherein the plurality of post interconnects are located laterally between the first metallization portion and the second metallization portion.

5. The package of claim 1,
wherein the first metallization portion includes a first dielectric layer and a first plurality of metallization interconnects, and
wherein the second metallization portion includes a second dielectric layer and a second plurality of metallization interconnects.

6. The package of claim 5, wherein the plurality of pillar interconnects comprise:
a first plurality of pillar interconnects coupled to the first plurality of metallization interconnects of the first metallization portion;
a second plurality of pillar interconnects coupled to the second plurality of metallization interconnects of the second metallization portion; and
a third plurality of pillar interconnects coupled to the plurality of post interconnects.

7. The package of claim 6, wherein a pillar interconnect from the first plurality of pillar interconnects is coupled to, touching and misaligned with a metallization interconnect from the first plurality of metallization interconnects.

8. The package of claim 6, wherein a pillar interconnect from the second plurality of pillar interconnects is coupled to, touching and misaligned with a metallization interconnect from the second plurality of metallization interconnects.

9. The package of claim 6, wherein a pillar interconnect from the third plurality of pillar interconnects is coupled to, touching and misaligned with a post interconnect from the plurality of post interconnects.

10. The package of claim 1, wherein the first metallization portion partially overlaps vertically with the integrated device.

11. The package of claim 1, wherein the first metallization portion completely overlaps vertically with the integrated device.

12. The package of claim 1,
wherein the first metallization portion is coupled to the integrated device through a first plurality of pillar interconnects and the first plurality of solder interconnects,
wherein the second metallization portion is coupled to the integrated device through a second plurality of pillar interconnects and the second plurality of solder interconnects, and
wherein the first plurality of pillar interconnects and the second plurality of pillar interconnects are different from the plurality of pillar interconnects.

13. The package of claim 12,
wherein the first plurality of pillar interconnects are part of the first metallization portion, and
wherein the second plurality of pillar interconnects are part of the second metallization portion.

14. The package of claim 1, wherein the plurality of pillar interconnects are located outside of the encapsulation layer.

15. The package of claim 1, wherein the plurality of pillar interconnects include a width that is different from a width of a post interconnect from the plurality of post interconnects.

16. The package of claim 1, wherein the plurality of pillar interconnects include a width that is different from a width of a metallization interconnect from a plurality of metallization interconnects from the first metallization portion.

17. The package of claim 1 further comprising:
a third metallization portion coupled to the integrated device through a third plurality of solder interconnects; and
a fourth metallization portion coupled to the integrated device through a fourth plurality of solder interconnects.

18. A method for fabricating a package, comprising:
providing an integrated device, wherein a plurality of post interconnects are coupled to the integrated device;
coupling a first metallization portion to the integrated device through a first plurality of solder interconnects;
coupling a second metallization portion to the integrated device through a second plurality of solder interconnects;
forming an encapsulation layer that at least partially encapsulates the integrated device, the first metallization portion, the second metallization portion, the plurality of post interconnects, the first plurality of solder interconnects and the second plurality of solder interconnects; and
forming a plurality of pillar interconnects that are coupled to the first metallization portion, the second metallization portion and the plurality of post interconnects.

19. The method of claim 18,
wherein the first metallization portion is coupled to a first plurality of pad interconnects of the integrated device through the first plurality of solder interconnects, and
wherein the second metallization portion is coupled to a second plurality of pad interconnects of the integrated device through the second plurality of solder interconnects.

20. The method of claim 19, wherein the plurality of post interconnects are coupled to and touching a third plurality of pad interconnects of the integrated device.
